(19) United States
(12) Patent Application Publication
(10) Pub. No.: US 2026/0368113 A1
(43) Pub. Date: Nov. 19, 2026

(54) COMPUTER-IMPLEMENTED METHOD FOR CO-SIMULATION

(71) Applicant: dSPACE SE & Co. KG, Paderborn (DE)

(72) Inventor: Rafael YUNIS, Zagreb (HR)

(73) Assignee: dSPACE SE & Co. KG, Paderborn (DE)

(21) Appl. No.: 19/725,170

(22) Filed: Jun. 30, 2026

Related U.S. Application Data
(63) Continuation of application No. PCT/EP2025/059290, filed on Apr. 4, 2025.

(30) Foreign Application Priority Data
Apr. 4, 2024 (EP) 24168399.4

(51) Int. Cl. G06F 13/20

(52) U.S. Cl. CPC G06F 13/20; G06F 2213/40

(57) ABSTRACT

A method for temporally consistent message processing in co-simulation, using two simulators that operate asynchronously and exchange messages via a communication channel having a FIFO buffer. Each message contains a time stamp that indicates the simulation time of the sending simulator. A playback time and an estimated current time of the sending simulator are determined and dynamically updated in the receiving simulator, based on the time stamp. Arriving messages are stored, discarded, or provided for output, depending on the time reference. Tolerance thresholds are taken into account to compensate for slight time deviations. For a longer time delay, the playback time may be advanced in an accelerated manner, with observance of a minimum time between such skips. The method allows robust, flexible, and efficient synchronization without cyclical communication.

This nonprovisional application is a continuation of International Application No. PCT/EP2025/059290, which was filed on Apr. 4, 2025, and which claims priority to European Patent Application No. 24168399.4, which was filed on Apr. 4, 2024, and which are both herein incorporated by reference.

### BACKGROUND OF THE INVENTION

### Field of the Invention

The invention relates to a computer-implemented method for co-simulation, using a first simulator and a second simulator, with a communication channel being provided between the two simulators, via which messages are transferable from the first simulator to the second simulator, in that the first simulator delivers a particular message to the communication channel.

### Description of the Background Art

The company dSPACE offers, under the name “SCALEXIO,” a system for carrying out real-time simulations and implementing hardware-in-the-loop (HIL) test environments, which is provided in particular for developing and validating control devices and systems in the automotive industry. An overview of SCALEXIO is submitted herewith in the attached Appendixes 1, 2, and 3, which are incorporated by reference.

Simulation is an indispensable tool in current product development, in particular in fields with stringent requirements for safety and reliability. Real-time simulations and hardware-in-the-loop tests provide the option for testing the behavior of control devices and systems under realistic conditions without the need for physical prototypes or actual operating conditions. This reduces development times and costs, and at the same time increases product quality and safety.

However, traditional simulation and test environments reach their limits when complex systems and highly dynamic applications are involved. The requirements for flexibility, scalability, and performance are continuously increasing. Therefore, there is an urgent need for more advanced approaches that are capable of efficiently simulating and testing the increasingly complex and interlinked systems. These challenges are addressed by providing an advanced real-time simulation and HIL test system, known as SCALEXIO. SCALEXIO is a modular, scalable system that has been developed by dSPACE in order to meet the demanding requirements of current development and test environments. A flexible platform is provided for the simulation and testing of control devices and systems over a broad spectrum of applications and fields. The core functions include support for complex modeling, real-time simulations, and extensive I/O configurations and user-friendly interfaces for system configuration and monitoring. As a result of its modular architecture, SCALEXIO can be easily adapted to specific requirements and scaled for various simulation scenarios, which makes it a versatile tool in the development and testing landscape.

In addition, dSPACE offers the VEOS platform, which is a comprehensive platform for virtual validation that has been developed specifically for supporting software-in-the-loop (SIL) simulations. These functions allow developers and engineers to perform development and testing of control device software and complex system models in a completely virtual environment. VEOS provides multiple key functions and advantages in the context of SIL simulations.

VEOS allows the creation of virtual ECUs in order to simulate the software of control devices independently of physical hardware. This is particularly useful in the early phases of development, when the actual hardware is possibly not yet available. The platform supports the integration of models that have been created in various modeling languages and tools, such as MATLAB/Simulink, to enable wide-ranging system simulation. This allows seamless simulation of the interplay between control device software and the system model to be controlled. VEOS provides interfaces to tools for automation of tests which allow efficient implementation and management of large quantities of test cases. This helps to improve the software quality and shorten the development time. Extensive diagnostic and visualization tools for VEOS facilitate the identification and analysis of problems in simulated control device software and in the system model.

VEOS also allows the definition and execution of scenarios that emulate actual operating conditions. This helps developers to understand how the software will behave under various conditions. Due to the support of simulations encompassing numerous technical fields (mechanics, electrical systems, hydraulics, for example), VEOS provides a comprehensive view of the system behavior and promotes interdisciplinary cooperation. The modular architecture of VEOS makes it easy to adapt the platform to specific project requirements, and allows scaling to the complexity of the systems being developed. VEOS supports customary industry standards and interfaces, which facilitates integration into existing development processes and the reuse of models and test cases. As a result of these functions, VEOS enables effective, efficient implementation of SIL simulations, resulting in a universal tool in current system and software development, in particular in the automotive field.

In co-simulation, HIL and SIL systems are integrated in such a way that they are able to run simultaneously and synchronously. This means that portions of the system are simulated in real time on physical hardware (HIL), and other portions are simulated in parallel in a virtual environment (SIL). This integration allow comprehensive system testing in which it is possible to assess the interaction between the software and the actual hardware, as well as the interplay of various system components.

The typical approach for co-simulations and the common understanding of co-simulations in the prior art are that a component or a subsystem takes over the timing of the entire simulation system, so that the component or subsystem is generally referred to as a simulation master. The present invention does not deal with this type of co-simulation (also referred to as “strong coupling”), but, rather, concentrates on a simulation system made up of two subsystems which are independent simulators (for example, VEOS and SCALEXIO, as discussed above), and instead of incorporating an external simulation master or using one of the simulators as a timing controller, allows both simulators to maintain their timing behavior and to easily exchange data whenever they are available. This co-simulation approach is also referred to as “loose coupling.”

This approach has the advantage that it enhances the simulation performance by decreasing the idle times of both simulator components and reducing the risk of a timeout (task overrun) in the real-time simulator (HIL). However, this has the drawback that the overall system is not deterministic, and temporal inconsistencies may arise in the communication. These inconsistencies may be, for example, drift between the simulator clock pulses, loss of messages, delay in the receipt of messages, or “jitter” in the bus timing interval, to name only a few examples.

Because of these disadvantages, this loose coupling approach is often not considered for co-simulation in current products and technologies, and strong coupling approaches are frequently preferred instead. However, strong coupling may be unsuitable for many simulation systems, in particular for actual examples that are computationally intensive.

For an SIL simulation step that lasts longer than with the HIL system in real time, in the SIL system loose coupling results in only a minor delay in the message communication, and not in the loss of real-time capability of the HIL simulator. Loose coupling may also involve a type of buffering in order to provide greater data consistency. In the case of bus simulation data exchange, it is also common to exchange bus messages only when they are available.

However, in a loose coupling approach problems may arise with the coupling of the HIL simulator to the SIL simulator. As described above, it is possible that the SIL simulator may temporarily not be running in time with the HIL simulation, since a portion of the simulation steps in the SIL system last longer than the clock pulse duration that is specified by the clock pulse of the co-simulation, and further subsequent steps are then carried out in rapid succession to compensate for this delay. This situation may result in several unintended consequences in the bus timing behavior. In particular, extended delays on the SIL simulator may result in extremely long queues and, when these queues become excessively long, may result in data losses.

In distributed simulation systems, which may be implemented by combining the VEOS platform (for SIL simulations) and SCALEXIO platform (for HIL simulations), the challenge is that different simulators can operate with simulation parameters that are different from one another. In particular, differences may occur in the so-called base step time of the involved simulators. This means that the individual simulators simulate with different time resolutions and increments, which may result in inconsistencies and problems with synchronization and data exchange.

In addition, the individual simulators often require only a partial quantity of the simulation data that are generated or processed in the overall system. In such cases, the concept of a centralized, temporally clocked buffer system in which all system data are globally held and distributed at fixed times (in the form of cyclical accumulation buffers or global data queues, for example) has proven to be inefficient and not very scalable. This is true in particular when the structure of the communication dynamically changes during run time, for example due to the addition or removal of communication channels, or the targeted request for additional data by individual simulators, which typically occurs in publish/subscribe-based architectures.

If a rigidly cyclical communication scheme is now relied on, in which every channel exchanges a message in each simulation step, regardless of the actual data volume or the specific need for communication, this results in significant overhead. In the process, too many communication operations are initiated, which in particular for a large number of simulators and channels may result in significant strain on the system resources and an increase in latency. This may have adverse effects on the overall efficiency of the co-simulation, and in real-time environments may even result in task overruns or data losses.

The described requirements make it clear that traditional communication approaches having fixed clock rates and centralized buffer systems are not suitable for depicting the complexity and dynamics of present-day co-simulation scenarios. Rather, there is a need for a communication structure that supports loose coupling between the simulators as well as flexible handling of simulation data.

A method for synchronizing a simulation with a real-time system is known from DE 10 2017 214 125 A1, which corresponds to US 2020/0257835, which has the following method steps: A message of the real-time system is awaited, a receive time of the message is measured, at least one further message of the real-time system is awaited, the receive time of the further message is measured, a time difference between the receive times is formed, a deviation of the time difference from a predefined macro increment of the simulation is ascertained, and a start time of the simulation is determined based on the deviation.

WO 2019/219796 A1, which corresponds to US 2021/0081585, which is incorporated herein by reference, describes a method for event-based simulation of a system, wherein the simulation is performed on a computer system comprising a first computing unit and at least one second computing unit, the first computing unit has a simulation time, the second computing unit has an operating system layer and an application layer, the second computing unit has a system time in the operating system layer, at least the second computing unit executes a simulator application, at least one simulation object is executed on the simulation application, the first computing unit manages an event queue, at least one event per simulation step is listed in the event queue, a process to be executed by the simulation object and a simulation time provided for execution of the process are associated with the event, and the second computing unit has a virtual clock generator. The method has the following steps for each simulation step: transmitting, by the first computing unit, a start signal to the virtual clock generator to execute a next simulation step in the second computing unit, and, based on a time difference between a past simulation step and the simulation time period, incrementing the system time of the second computing unit, and executing the upcoming process at the simulation time associated with the process.

### SUMMARY OF THE INVENTION

It is therefore an object of the present invention to provide an approach that allows the data exchange to be kept low while at the same time maintaining the data integrity in the simulators.

According to an example of the invention, a computer-implemented method for co-simulation using a first simulator and a second simulator is thus provided, with a communication channel being provided between the two simulators, via which messages are transferable from the first simulator to the second simulator, in that the first simulator delivers a particular message to the communication channel, and the communication channel includes a FIFO buffer, the first simulator operates with a first simulator time and the second simulator operates with a second simulator time, and the messages each include a piece of data, and a time stamp t that indicates the first simulator time at the time of creation of the message in the first simulator and/or indicates the first simulator time at the time of transfer of the message to the communication channel.

The method according to the invention comprises the following method steps:
S1) periodically checking whether messages from the first simulator have been received in the communication channel, wherein the periodic checking takes place in the second simulator time with a period δtₛ at query times tₛ, tₛ+δtₛ, tₛ+2δtₛ, tₛ+3δtₛ, . . . ,
S2) receiving the messages of the first simulator that are available in the communication channel at the particular query time and processing the messages received at the particular query time in subsequent steps S3 through S6 in the order of the respective time stamp t of the particular messages until all received messages are processed, and then switching to step S7a or S7b,
S3) if a received message is the first message received via the communication channel, setting a playback time Tₚ of the second simulator and an estimated current first simulator time Tₚ₀ of the other simulator to the time stamp t of the first message received via the communication channel, i.e., Tₚ:=t and Tₚ₀:=t, and storing the message in the FIFO buffer,
S4) if a received message is not the first message received via the communication channel and t>Tₚ applies for the received message, storing the message in the FIFO buffer,
S5) if a received message is not the first message received via the communication channel and t>Tₚ does not apply for the received message, and with regard to the estimated current first simulator time Tₚ₀ and the time stamp T, Tₚ₀−t<τₐ applies, where τₐ is a predetermined first limit value, storing the message in the FIFO buffer and setting the playback time Tₚ to the time stamp t of the received message, i.e., Tₚ:=t,
S6) if a received message is not the first message received via the communication channel and t>Tₚ does not apply for the received message, and for the estimated current first simulator time Tₚ₀, Tₚ₀−t<τₐ does not apply, discarding the message,
S7a) if Tₚ₀−Tₚ>τ_{b} does not apply, where τ_{b} is a predetermined second limit value, increasing the playback time Tₚ and the estimated current first simulator time Tₚ₀ by one period δtₛ in each case, i.e., Tₚ:=Tₚ+δtₛ and Tₚ₀:=Tₚ₀+δtₛ,
S7b) if Tₚ₀−Tₚ>τ_{b} applies, increasing the playback time Tₚ by a multiple n of the period δtₛ and increasing the estimated current first simulator time Tₚ₀ by a period δtₛ, i.e., Tₚ:=Tₚ+n δtₛ and Tₚ₀:=Tₚ₀+δtₛ, where n>1,
S8) detecting the first message in the FIFO buffer that is waiting for output,
S9) if t>Tₚ₀ applies to this message with regard to the time stamp t and the estimated current first simulator time Tₚ₀, setting the estimated current first simulator time Tₚ₀ to the time stamp t of the message, i.e., Tₚ₀:=t,
S10a) if t<Tₚ applies to this message with regard to the time stamp t and the playback time Tₚ, outputting the message to the second simulator, deleting the message in the FIFO buffer, and repeating step S8,
S10b) if t<Tₚ does not apply to this message with regard to the time stamp t and the playback time Tₚ, there is no further detection of messages in the FIFO buffer.

The method according to the invention may thus be divided into three parts:
1. A periodic check takes place in step S1. If it is determined in step S1 that messages are available in the communication channel, these messages are received in step S2. Steps S1 and S2 take place practically in parallel and independently of the steps described below. With steps S1 and S2, in effect the messages that are processed in the subsequent steps are provided.
2. The messages received at the particular query time are then processed in subsequent steps S3 through S6 until all last received messages are processed. A switch to step S7a or S7b then takes place.
3. In the steps beginning with S7a or S7b through S10b, messages that have been stored in the FIPO buffer are then processed in order to selectively output them to the second simulator.

The consideration of two simulators is by way of example. In principle, the invention may be expanded to any number of simulators of a co-simulation that exchange data with one another via respective communication channels. There may be multiple communication channels that operate between the first simulator and the second simulator by use of the method according to the invention.

Receiving simulators or sending simulators that use the same communication channel are also possible in principle. In this case, the exchanged messages should additionally contain a simulator ID. Furthermore, individual values for Tₚ, Tₚ₀ and a separate FIFO buffer are to be kept for each involved simulator. In addition, the other method steps described above and explained below should then take place in the same manner as described above, but in each case individually for each simulator ID.

When it is stated that the time stamp t indicates the first simulator time at the time of creation of the message in the first simulator and/or the first simulator time at the time of transfer of the message to the communication channel, the time stamp does not have to directly indicate the particular first simulator time. Rather, the time stamp may be a function of this first simulator time. The time stamp t indicates the first simulator time at the time of creation of the message in the first simulator as well as the first simulator time at the time of transfer of the message to the communication channel when the message upon creation is also directly provided to the communication channel.

The invention thus relates to a method for improved buffering and temporal control of messages in a distributed co-simulation environment, in particular in a combination of hardware-in-the-loop (HIL) and software-in-the-loop (SIL) simulations for which there is no requirement for cyclical, globally synchronized communication between the involved simulators. Rather, the method is based on a so-called loose coupling approach in which the simulators typically operate with different base clock times, run asynchronously, and exchange data only when the data are actually present. This imposes special demands on the buffering and timing behavior of the communication interfaces.

Thus far, temporally clocked buffer systems, for example, have been used in which, for example, the filling level of a message queue was used to determine the correct output point. However, in the context of present-day service-based architectures, in particular in dynamic publish/subscribe systems, such concepts are no longer practicable. With that approach, communication channels can change during run time, and not all simulation partners require the same data volume at the same time. Dispensing with cyclical message transfer reduces the complexity of communication, but requires new mechanisms to preserve temporal consistency between the simulators.

The method according to the invention replaces the derivation of the output time from the filling level of the message buffer, as previously used, with a time stamp-based mechanism. The simulation time stamp of the sending simulator is associated with each received message. This time stamp is used in the receiving system to reconstruct two parameters: a playback time Tₚ at which the received message is to be output, and an estimated current simulation time Tₚ₀ of the sending simulator. These two time variables are continuously updated and correlated with one another in order to decide, using a flexible set of rules as a function of freely selectable tolerance values, whether messages are to be stored, further processed, or discarded.

By use of this logic system, the method can functionally recreate the original message buffering from synchronous co-simulations without having to rely on cyclical messages or global synchronization mechanisms. At the same time, the architecture allows individual communication channels to be operated independently of one another, which provides significant advantages in particular in service-oriented, distributed simulation environments with heterogeneous requirements and load profiles. The invention thus provides the basis for high-performance, scalable, and robust message buffering and replay in co-simulation systems.

Although the method according to the invention can operate with a service-based communication structure, it is not limited to this application. Rather, the proposed method is generally applicable and may also be used in other communication scenarios in which different simulators interact with one another, regardless of the underlying communication architecture. Even in the case of service-based implementation, the invention does not specify a certain communication layer or a specific protocol. Rather, the method is designed independently of protocols and allows use of any transfer technology, for example Ethernet on the physical level or protocols such as Data Distribution Service (DDS) on the application level.

Within the scope of the invention, the term “service-based communication” refers to a communication architecture in which the exchange of data between the simulators takes place via a service-oriented model. Instead of a continuous, cyclical data transfer between fixedly connected communication partners, the communication is based on a flexible and dynamically adaptable structure of services that can provide and call up data. This allows a decoupled interaction between the simulators, so that they do not have to be directly connected to one another. Instead, they can publish, subscribe, or poll information as needed, resulting in greater flexibility in the data exchange. It is possible for connections to be established between the simulators at any time during the simulation, and for communication channels to be set up or discontinued during run time.

The focus of the invention is not the specific configuration of the communication infrastructure, but, rather, the reception process that ensures correct temporal classification of the received messages into the local time system of the receiving simulator. The objective, in particular in distributed co-simulation scenarios having a mixture of real-time and nonreal-time simulators, is to enable consistent, temporally coherent message replay.

In light of this background, the term “communication channel” within the scope of the invention is functionally and abstractly defined: A communication channel is a time-ordered group of messages that are exchanged between two or more simulators. Each message within such a channel bears a time stamp that represents the current simulation time of the sending simulator. The subject matter of the invention does not involve the exact grouping of the communication channels in terms of content or structure. A communication channel may depict, for example, an individual signal, a protocol data unit (PDU), a complete bus channel, or the entire bus or I/O communication between two simulators. This flexibility allows wide applicability of the method according to the invention in various system configurations and simulation architectures.

For each open communication channel between the involved simulators, the method according to the invention provides a separate send/receive interface. Each of these interfaces includes a main function for communication that is triggered in fixed time increments, and these cycles are measured in the local simulation time of the particular simulator. The communication function is thus called up periodically with a constant simulation time period, and in each case operates at the current local simulation time.

Within each send/receive interface, multiple internal data structures are available which are relevant for message handling and temporal control. These include, first of all, a first in first out (FIFO) buffer in which the messages to be transferred via the particular channel are stored. This structure ensures that the messages are processed and sent in the order of their arrival.

In addition, each interface manages the playback time Tₚ, which indicates at which simulation time received messages are provided for output to the second simulator. This playback time is dynamically adapted to maintain the temporal integrity of the simulated communication sequences. In addition, an estimated current simulation time Tₚ₀ of the first simulator is included. This value is used to temporally classify received messages in the context of the communication partner, and is of key importance in particular for assessing the validity and relevance of a message within the scope of the buffer mechanism. This structure allows precise, decoupled control of the message transfer, with each interface being able to operate independently. This assists with the scalability and modularity of the method, in particular in distributed co-simulation environments with asynchronously operating components.

Use of the method according to the invention together with the associated buffer mechanism is advantageous not only in a hardware-in-the-loop (HIL) simulator for receiving data from a software-in-the-loop (SIL) simulator, but also with respect to an SIL simulator. Although it is true that, due to drift and jitter of the simulation time of the SIL simulator with respect to the real-time clock of the HIL system, a buffer is necessary to allow injection of messages having correctly matched timing, the converse is also true: From the viewpoint of the SIL simulator, the real time of the HIL system is likewise subject to drift relative to its own simulation time, since all components in the SIL system are executed based solely on the local simulation time. Consequently, in principle, buffering is always advantageous when two simulators communicate with one another and rely on mutually independent, locally kept time systems that are not fully synchronized. This applies regardless of which of the two time systems is regarded as “real” or “real-time.” Thus, the proposed method represents a universal solution for temporally consistent communication between simulators having different clock generators, and allows robust decoupling of the systems while at the same time preserving the temporal correctness of the transferred messages.

The above aspects are considered in the examples of the invention described below.

The playback time Tₚ can be increased by a multiple n of the period δtₛ only if the time difference, measured in the second simulator time, between the point in time of the pending increase in the playback time Tₚ by a multiple n of the period δtₛ, and the point in time of the most recent increase in the playback time Tₚ by a multiple n of the period δtₛ, is greater than a predetermined time difference. According to one refinement of the invention, n<3, and preferably n=2.

The messages received in step S2 at the particular query time can be processed in the subsequent steps in the order in which they are present in the communication channel, provided that their respective time stamps t are equal.

According to an example of the invention, τ_{b} can be a dynamic value that is changed in the course of the method. This value may be a function of a parameter of the co-simulation, for example of a statistical value that is a function of (Tₚ₀−Tₚ), such as an average thereof, or the standard deviation.

The service-based communication can use middleware that takes over management of the communication channel, synchronization of the messages, and provision of the relevant data for the individual simulators. This avoids the requirement for all participants to exchange all data in each simulation step and thus reduces the communication load. The middleware may be a Data Distribution Service (DDS), for example. The invention thus allows use of service-based middleware, but also functions without such middleware and thus provides similar properties with regard to the transferred data volume.

One of the simulators may operate in real time, and the other simulator may operate in a simulator time that is different from real time.

The invention further relates to a computer system including a processor that is configured in such a way that, during operation, it carries out the steps of a method described above.

The invention further relates to a computer program that includes commands which, when executed by a computer system, prompt the computer system to carry out the steps of a method described above.

The invention further relates to a computer-readable memory medium on which this computer program is stored.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a schematic flow chart of a method according to an example; and

FIG. 2 shows a more complex flow chart of this method with its conditions and branches.

### DETAILED DESCRIPTION

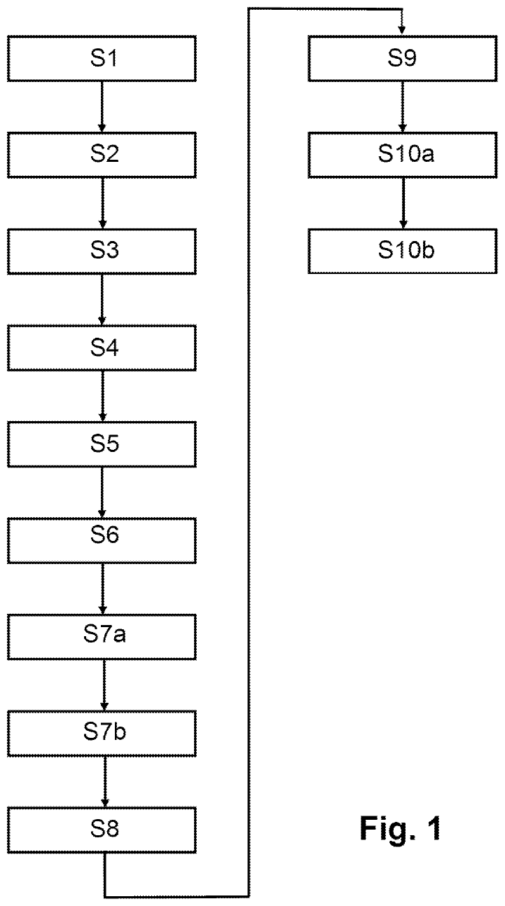

The method illustrated in FIG. 1 is designed as a computer-implemented method for performing co-simulation using a first simulator (an SIL system, for example) and a second simulator (an HIL system, for example), between which a communication channel is provided. Messages may be transferred from the first simulator to the second simulator via this communication channel. The communication channel includes a FIFO buffer for temporary storage of received messages. The first simulator operates with a first simulator time (a simulation time, for example), and the second simulator operates with a second simulator time (real time or likewise a simulation time, for example). In addition to the data content, each transferred message includes a time stamp t that represents the first simulator time at the time of creation of the message in the first simulator and/or at the time of transfer to the communication channel.

The method follows a cyclical execution loop that is periodically run through with a fixed time period δₜₛ, with the clocking taking place according to the second simulator time. The central control of the receipt and processing of the messages takes place in this loop, the method comprising the following steps:
Step S1: Periodic Check for New Messages

At fixed query times tₛ, tₛ+δtₛ, tₛ+2 δtₛ, tₛ+3 δtₛ, . . . , etc., it is checked whether new messages from the first simulator have arrived in the communication channel. This cyclical query ensures that the method can continuously respond to new incoming data without cyclically generating outgoing messages, which in particular in loose coupling architectures greatly reduces the communication load.
Step S2: Receipt and Temporal Sorting

All messages that are available in the communication channel at a given query time are received. The received messages, sorted in the order of their respective time stamp t, are then handled for further processing. If multiple messages have the same time stamp, their order is considered according to arrival in the channel. This allows deterministic processing while at the same time preserving the chronological order.
Step S3: Initialization for the First Message

If the received message is the first message received via this communication channel, two key time variables are initialized: the playback time Tₚ and the estimated current time Tₚ₀ of the first simulator. Both values are set to the time stamp t of the received message. The message is stored in the FIFO buffer. This initialization ensures that the playback system from the outset has a temporally consistent reference level.
Step S4: Messages with Time Stamp t>Tₚ

If the time stamp t of the received message is greater than the current playback time Tₚ, the message is stored in the FIFO buffer. These messages are provided for replay in a future cycle.
Step S5: Messages with t≤Tₚ and a Small Time Delay

If the time stamp t is less than or equal to Tₚ but within a predefined tolerance window (Tₚ₀−t<τₐ), the message is likewise stored. In addition, the playback time Tₚ is set to the time stamp t of the message. This step allows slightly delayed messages to still be considered, thus increasing robustness with respect to slight communication delays.
Step S6: Discarding of Outdated Messages

If the time stamp t of the message is less than or equal to Tₚ and the difference from the estimated current time Tₚ₀ is too great (Tₚ₀−t≥τₐ), the message is considered to be outdated and is discarded. This prevents outdated or inconsistent data from being fed into the simulation system.
Step S7a: Regular Advancement of the Playback Time

If the time difference between Tₚ₀ and Tₚ is not greater than a second limit value τ_{b}, the playback time Tₚ and the estimated time Tₚ₀ are each increased by a period δtₛ. This step represents the normal case, and ensures continuous advancement of the playback time for essentially synchronous communication.
Step S7b: Accelerated Advancement for a Large Backlog

However, if the time difference Tₚ₀−-Tₚ is greater than τ_{b}, the playback time Tₚ is advanced forward by a multiple n of δtₛ (Tₚ:=Tₚ+nδtₛ) to clear backlogs. At the same time, Tₚ₀ is only increased by δtₛ. However, to avoid excessive acceleration, this “beat skip” mechanism is triggered only when the time, measured in the second simulator, that has elapsed since the last such skip is a predefined minimum time. This stabilizes the method and prevents excessive advancement of Tₚ, which otherwise could result in lost messages. A value of n=2 has proven to be particularly suitable in practice.
Step S8: Selection of the Next Message for Output

The first message present in the FIFO buffer that is waiting for output is identified.
Step S9: Synchronization of the Estimated Time Tₚ₀

If the time stamp t of the selected message is greater than Tₚ₀, Tₚ₀ is set to t. This correction ensures dynamic adaptation of the estimated time of the partner simulator to the messages that are actually received.
Step S10a: Message is Ready for Output

If the time stamp t of the message is less than the current playback time Tₚ, the message is output to the second simulator and removed from the FIFO buffer, and the sequence returns to step S8 to process the next message.
Step S10b: End

If the condition t<Tₚ is not met, there is no further detection of the messages in the FIFO buffer.

The described method ensures that received messages are processed in such a way that the temporal integrity of the co-simulation as well as robustness against communication latencies and jitter are provided. The use of Tₚ and Tₚ₀ as key time variables allows messages, even without external synchronization, to be correctly classified. The combination of a dynamically regulated playback time, selective buffering, and an adaptive beat skip mechanism results in a flexible framework for handling asynchronous communication in distributed simulation systems. The communication load is thus minimized, and at the same time a consistent replay of data with high temporal precision is enabled.

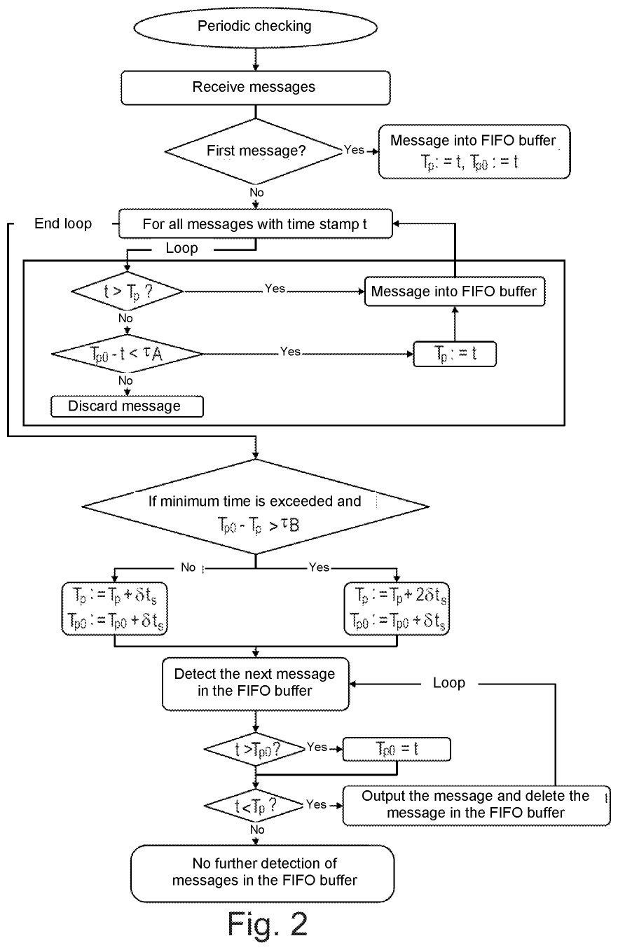

This is also illustrated in detail in FIG. 2, in which all conditions and branches of the method according to an example of the invention described here are apparent.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A computer-implemented method for co-simulation using a first simulator and a second simulator, wherein:
a communication channel is provided between the first and second simulators, via which messages are transferable from the first simulator to the second simulator, in that the first simulator delivers a particular message to the communication channel,
the communication channel includes a FIFO buffer,
the first simulator operates with a first simulator time and the second simulator operates with a second simulator time, and
the messages each include a piece of data, and a time stamp t that indicates the first simulator time at the time of creation of the message in the first simulator and/or indicates the first simulator time at the time of transfer of the message to the communication channel,
the method comprising:
S1) periodically checking whether messages from the first simulator have been received in the communication channel, wherein the periodic checking takes place in the second simulator time with a period δtₛ at query times tₛ, tₛ+δtₛ, tₛ+2δtₛ, tₛ+3δtₛ, . . . ;
S2) receiving the messages of the first simulator that are available in the communication channel at the particular query time and processing the messages received at the particular query time in subsequent steps S3 through S6 in the order of the respective time stamp t of the particular messages until all received messages are processed, and then switching to step S7a or S7b;
S3) if a received message is the first message received via the communication channel, setting a playback time Tₚ of the second simulator and an estimated current first simulator time Tₚ₀ of the other simulator to the time stamp t of the first message received via the communication channel, i.e., Tₚ:=t and Tₚ₀:=t, and storing the message in the FIFO buffer;
S4) if a received message is not the first message received via the communication channel and t>Tₚ applies for the received message, storing the message in the FIFO buffer;
S5) if a received message is not the first message received via the communication channel and t>Tₚ does not apply for the received message, and with regard to the estimated current first simulator time Tₚ₀ and the time stamp t, Tₚ₀−t<τₐ applies, where τₐ is a predetermined first limit value, storing the message in the FIFO buffer and setting the playback time Tₚ to the time stamp t of the received message, i.e., Tₚ:=t;
S6) if a received message is not the first message received via the communication channel and t>Tₚ does not apply for the received message, and for the estimated current first simulator time Tₚ₀, Tₚ₀−t<τₐ does not apply, discarding the message;
S7a) if Tₚ₀−Tₚ>τ_{b} does not apply, where τ_{b} is a predetermined second limit value, increasing the playback time Tₚ and the estimated current first simulator time Tₚ₀ by one period δtₛ in each case, i.e., Tₚ:=Tₚ+δtₛ and Tₚ₀:=Tₚ₀+δtₛ;
S7b) if Tₚ₀−Tₚ>τ_{b} applies, increasing the playback time Tₚ by a multiple n of the period δtₛ and increasing the estimated current first simulator time Tₚ₀ by a period δtₛ, i.e., Tₚ:=Tₚ+n δtₛ and Tₚ₀:=Tₚ₀+δtₛ, where n>1;
S8) detecting the first message in the FIFO buffer that is waiting for output;
S9) if t>Tₚ₀ applies to this message with regard to the time stamp t and the estimated current first simulator time Tₚ₀, setting the estimated current first simulator time Tₚ₀ to the time stamp t of the message, i.e., Tₚ₀:=t;
S10a) if t<Tₚ applies to this message with regard to the time stamp t and the playback time Tₚ, outputting the message to the second simulator, deleting the message in the FIFO buffer, and repeating step S8; and
S10b) if t<Tₚ does not apply to this message with regard to the time stamp t and the playback time Tₚ, there is no further detection of messages in the FIFO buffer.

2. The computer-implemented method according to claim 1, wherein in step S7b the playback time Tₚ is increased by a multiple n of the period δtₛ only if the time difference, measured in the second simulator time, between the point in time tₛ of the pending increase in the playback time Tₚ by a multiple n of the period δtₛ, and the point in time t_{s last} of the most recent increase in the playback time Tₚ by a multiple n of the period δtₛ, is greater than a predetermined time difference.

3. The computer-implemented method according to claim 1, wherein n<3.

4. The computer-implemented method according to claim 1, wherein τ_{b} is a dynamic value that is changed in the course of the method.

5. The computer-implemented method according to claim 1, wherein the messages received in step S2 at the particular query time are processed in the subsequent steps in the order in which they are present in the communication channel, provided that their respective time stamps t are equal.

6. The computer-implemented method according to claim 1, wherein the co-simulation takes place via service-based communication.

7. The computer-implemented method according to claim 6, wherein the service-based communication uses middleware that takes over management of the communication channel, synchronization of the messages, and provision of the relevant data for the individual simulators.

8. The computer-implemented method according to claim 1, wherein one of the simulators operates in real time, and the other simulator operates in a simulator time that is different from real time.

9. A computer system, comprising a processor that is configured such that, during operation, it carries out the steps of the method according to claim 1.

10. A computer program that includes commands which, when executed by a computer system, prompt the computer system to carry out the steps of the method according to claim 1.

11. A computer-readable memory medium on which the computer program according to claim 10 is stored.
